(19) United States
(12) Patent Application Publication
(10) Pub. No.: US 2008/0233487 A1
(43) Pub. Date: Sep. 25, 2008

(54) Method and System for Optimizing Lithography Focus and/or Energy Using a Specially-Designed Optical Critical Dimension Pattern

(75) Inventors: Jacky Huang, Chu-Bei City (TW); Chih-Ming Ke, Hsin-Chu City (TW); Shinn Sheng Yu, Hsin-Chu (TW); Tsai-Sheng Gau, Hsin-Chu City (TW)

Correspondence Address: HAYNES AND BOONE, LLP, 901 Main Street, Suite 3100, Dallas, TX, 75202, US

(73) Assignee: TAIWAN SEMICONDUCTOR MANUFACTURING COMPANY, LTD., Hsin-Chu (TW)

(21) Appl. No.: 11/689,396

(22) Filed: Mar. 21, 2007

(51) Int. Cl. G03F 1/00; G03C 5/00; H01L 29/00

(52) U.S. Cl. 430/5; 257/499; 430/30

(57) ABSTRACT

Disclosed is a method and a system for optimizing lithography focus and/or energy using a specially-designed optical critical dimension pattern. A wafer comprising a plurality of photomasks is received. Critical dimension, line-end shortening, and side wall angle of the plurality of photomasks are measured using an integrated metrology equipment. A spectrum analysis is performed in a simulated spectra library to form analysis data. The analysis data is stored into a plurality of lookup tables of an optical critical dimension library. A lookup of the plurality of lookup tables is performed to determine a focus or energy of the wafer.

### BACKGROUND

The present disclosure relates in general to semiconductor manufacturing technology, and more particularly, to optimizing lithography focus and/or energy in semiconductor manufacturing technology. The present disclosure also relates to a method and system for optimizing lithography focus and/or energy using a specially-designed optical critical dimension pattern.

In semiconductor manufacturing technology, energy is required to activate photoresist when transferring a pattern from a reticle. The source of energy is typically in the form of radiation, such as an ultra-violet (UV) light source. In addition, the focus of such energy is also important in lithography. Focus is a condition where multiple individual rays of radiated energy are made to converge at a single point. Currently, lithography energy is monitored by examining a critical dimension (CD) of the exposed pattern, and lithography focus direction is monitored by examining line-end shortening and side-wall angle. Line-end shortening (LES) refers to the end-to-end space between photoresist lines and is sensitive to focus variations. Side-wall angle (SWA) refers to the profile of the photoresist after exposure to the energy source.

However, with current optical critical dimension (OCD) pattern designs of the photoresist, a focus direction may not be easily determined. In addition, the data quality and data resolution of the measurements by the current processes are poor. Therefore, a need exists for determining and optimizing energy or focus that provides good data quality and resolution. Furthermore, a need exists for a method and system that provides inline measurements, including CD, LES, and SWA measurements, from within the process tools for providing early error warnings based on the measurements. Further still, a need exists for a new OCD pattern that allows focus direction to be determined.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion. It is also emphasized that the drawings appended illustrate only typical embodiments of this invention and are therefore not to be considered limiting in scope, for the invention may apply equally well to other embodiments.

FIG. 1 is an exemplary optical critical dimension (OCD) pattern.

FIG. 2 is a diagram illustrating exemplary measurement of energy/focus from a photomask 10 in FIG. 1.

FIG. 3 is a graph of exemplary CD vs. focus measurements taken by detector 22 in FIG. 2.

FIG. 4 is a graph of exemplary line-end shortening (LES) and side-wall angle (SWA) vs. focus measurements taken by detector 22 in FIG. 2.

FIG. 5 is a process flow diagram of optimizing lithography focus and/energy.

FIG. 6 illustrates exemplary lookup tables in the OCD library.

FIG. 7 is a diagram of a specially-designed OCD pattern for optimizing lithography energy/focus.

### DETAILED DESCRIPTION

For the purposes of promoting an understanding of the principles of the invention, reference will now be made to the embodiments, or examples, illustrated in the drawings and specific language will be used to describe the same. It will nevertheless be understood that no limitation of the scope of the invention is thereby intended. Any alterations and further modifications in the described embodiments, and any further applications of the principles of the invention as described herein are contemplated as would normally occur to one skilled in the art to which the invention relates. Furthermore, the depiction of one or more elements in close proximity to each other does not otherwise preclude the existence of intervening elements. Also, reference numbers may be repeated throughout the embodiments, and this does not by itself indicate a requirement that features of one embodiment apply to another embodiment, even if they share the same reference number. The present disclosure provides a method and a system for optimizing lithograph focus and energy. Upon receiving a wafer having a plurality of patterns, critical dimension, line-end shortening, and side-wall angle of the plurality of patterns are measured using an integrated metrology equipment. All three measurements may be made simultaneously from within the process tools using the integrated metrology equipment. Once the measurements are made, a spectrum analysis is performed in a simulated spectra library to provide analysis data. The analysis data is then stored into a plurality of lookup tables of an optical critical dimension library and a lookup is performed to determine a focus or energy of the wafer. In this way, in-situ one shot measurement of focus or energy may be made. In addition to test wafers, this method and system may be extended to production wafers.

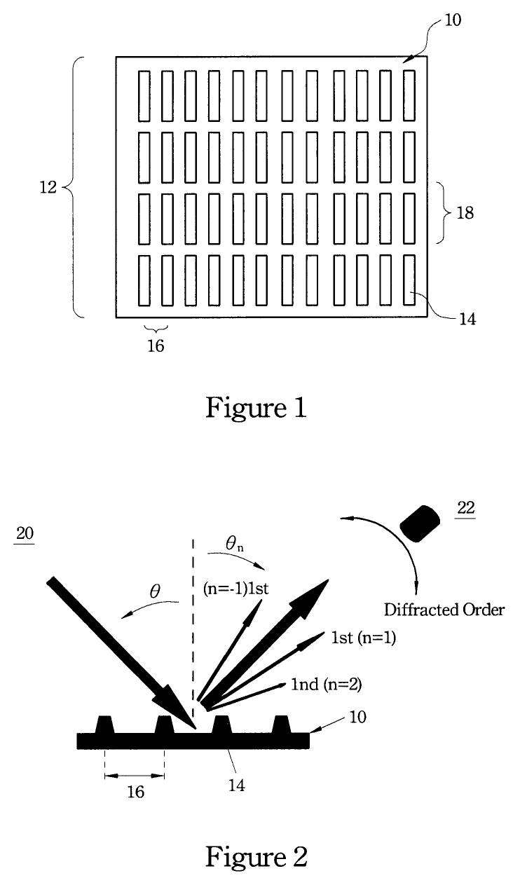

Referring to FIG. 1, a 80 μm×80 μm photomask 10 includes an optical critical dimension (OCD) pattern 12. OCD pattern 12 is a periodic type pattern comprising a plurality of segments 14. Each segment 14 has a width or gap of about 360 nm and a length of about 1600 nm. The plurality of segments 14 may have the same dimension and geometry. The pitch size, referring to the distance between the plurality of segments 14, in the x direction 16 is about 216 nm and the pitch size in the y direction is about 1960 nm. While critical dimension (CD), line-end shortening (LES) and side-wall angle (SWA) measurements may be taken from photomask 10, focus direction may not be determined from the periodic type OCD pattern 12.

Referring now to FIG. 2, a light source 20, such as a UV light source, is projected onto the photomask 10 and between each segment 14 at an angle of θ. This results in an energy/focus arrangement, such as is illustrated in FIG. 2. The segments 14 have a pitch size 16 in the x direction. A detector 22 measures the energy/focus diffracted from the photomask 10 at an angle of θₙ. The diffracted order of θₙ is referred to as the focus direction. Generally, the focus direction varies from n=−2 to n=+0.25. Detector 22 may take measurements of the critical dimension (CD) vs. focus, the line-end shortening (LES) vs. focus, and side-wall angle (SWA) vs. focus of photomask 10 simultaneously from within process tool using integrated metrology equipments.

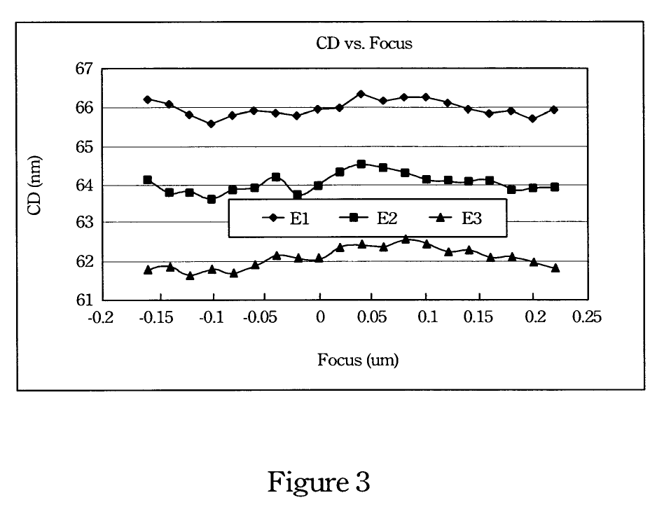

FIG. 3 is a graph of exemplary CD vs. focus measurements taken by detector 22 in FIG. 2. As shown in FIG. 3, three measurements of CD vs. focus are made for three different exposure energy E1, E2, and E3. In this example, the focus directions for E1, E2, and E3 range from −0.2 μm to 0.25 μm. The CD measurements for E1, E2, and E3 range from 61 to 67 nm.

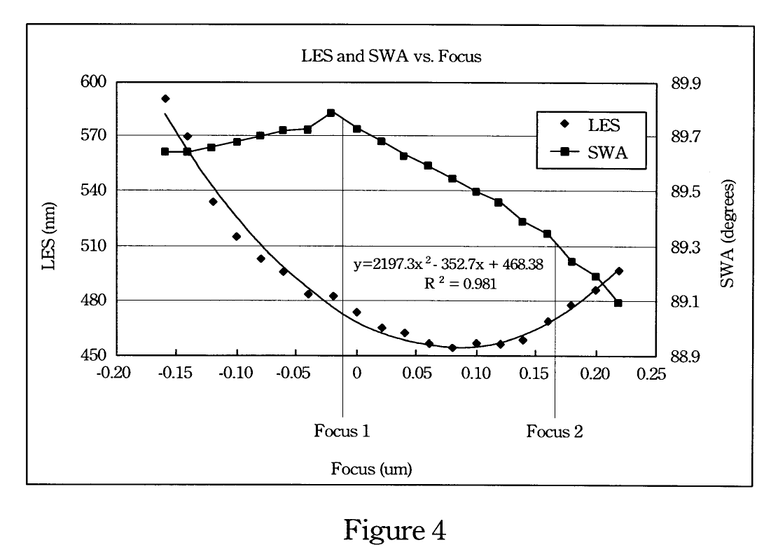

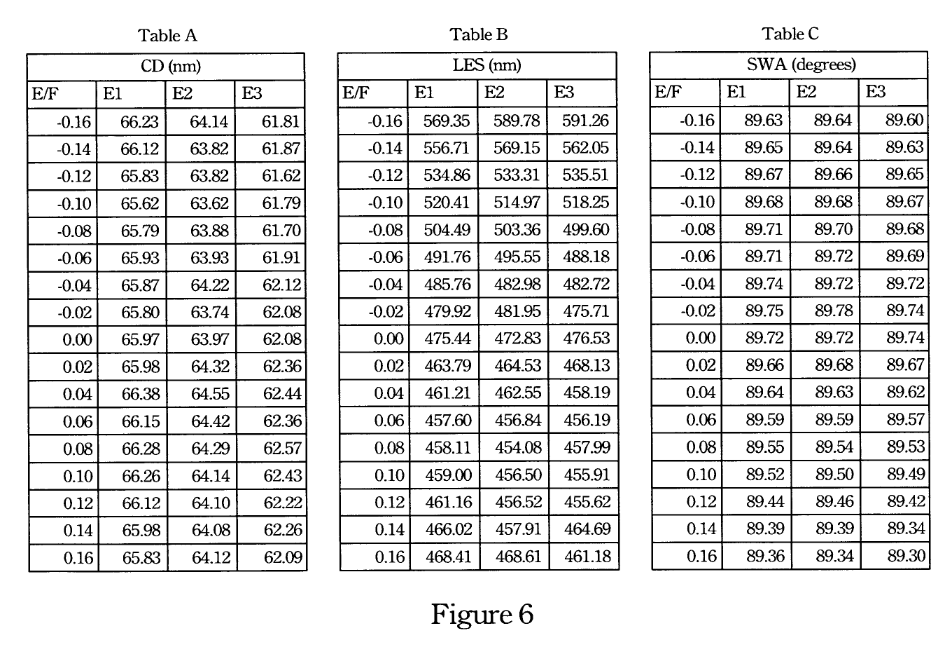

FIG. 4 is a graph of exemplary line-end shortening (LES) and side-wall angle (SWA) vs. focus measurements taken by detector 22 in FIG. 2. In this example, the focus directions for exposure energy E1, E2, and E3 also range from −0.2 μm to 0.25 μm. LES measurements for exposure energy E1, E2, and E3 range from 450 nm to 600 nm while SWA measurements for exposure energy E1, E2, and E3 range from 88.9 degrees to 89.9 degrees. In an illustrative embodiment, CD, LES, and SWA measurements from FIG. 3 may be taken simultaneously by detector 22 in FIG. 2 from within the process tools to provide early error warnings. More details regarding CD, LES, and SWA measurements are discussed in further detail with reference to FIG. 6 below.

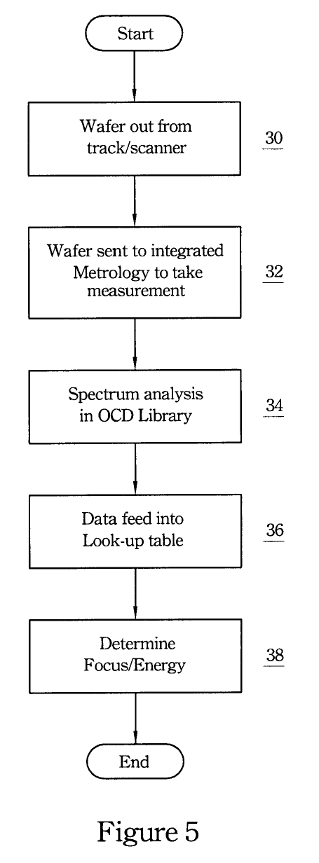

FIG. 5 is a process flow diagram of optimizing lithography focus and/or energy. As shown in FIG. 5, the process begins at step 30 when a test wafer, referred to as a focus energy monitoring (FEM) wafer, comprising a plurality of photomasks is received from a track or scanner. Track is a tool that is used to coat a photoresist or a bottom antireflective coating (BARC) on the silicon wafer. Scanner is a tool that is used to make patterns. At step 32, the test wafer is sent to integrated metrology equipments for measurements of CD, LES and SWA. Metrology equipments are integrated into process tools, such as a track, etch or chemical mechanical planarization (CMP) tool, to take measurements from within the process tools. It is noted that a production wafer may also be measured by the integrated metrology equipment at step 30 without departing the spirit and scope of the present disclosure.

At step 34, a spectrum analysis is performed in a simulated spectra library. Spectrum analysis includes comparing CD, LES, and SWA measurement results from the integrated metrology equipment against the results of a simulated spectra library. The simulated spectra library stores simulation results of the test wafer based on inputs such as pitch, various optical properties, materials stack, and a range. Pitch refers to the dimension between a plurality of segments of the photomask. The simulation is performed to determine whether the measured spectrum is sensitive to focus direction change.

Once the spectrum analysis is performed, at step 36, the analysis data is fed into lookup tables of an OCD library, such as OCD library shown in FIG. 6. Early error warnings may be provided based on the analysis data. More details regarding the lookup tables are discussed in further detail with reference to FIG. 6 below. From the analysis data in the lookup tables, at step 38, focus/energy and the focus direction may be determined for the test wafer. In this way, in-situ monitoring of focus or energy of the wafer and in-situ one shot measurement may be achieved. Thus, the process terminates thereafter.

Turning back to FIG. 4, focus/energy and focus direction may be determined based on a combination of LES measurements and SWA measurements v. focus. In an illustrative example, two focus positions, Focus 1 and Focus 2, may be determined from a lookup of LES values. However, in combination with SWA values, the real focus status may be determined. In this example, the real focus determined is Focus 2. Thus, with the simultaneous measurements of LES and SWA, a real focus or energy may be identified.

FIG. 6 illustrates exemplary lookup tables in the OCD library. Table A is a lookup table of energy/focus based on critical dimension measurements. Table A includes exemplary energy/focus data for critical dimensions of three different exposure energy E1, E2, and E3. Based on a measured critical dimension, a lookup is performed from Table A to determine energy/focus. Table B is a lookup table of energy/focus based on LES measurements. Table A includes exemplary energy/focus data for LESs of three different exposure energy E1, E2, and E3. Based on a measured LES, a lookup is performed from Table B to determine energy/focus. Table C is a lookup table of energy/focus based on SWA measurements. Table C includes exemplary energy/focus data for SWAs of three different exposure energy E1, E2, and E3. Based on a measured SWA, a lookup is performed from Table C to determine energy/focus. From tables A, B, and C, the focus direction ranging from −0.16 to 0.16 may be determined. The time of lookup from tables A, B, and C is usually very short, such as less than half a second.

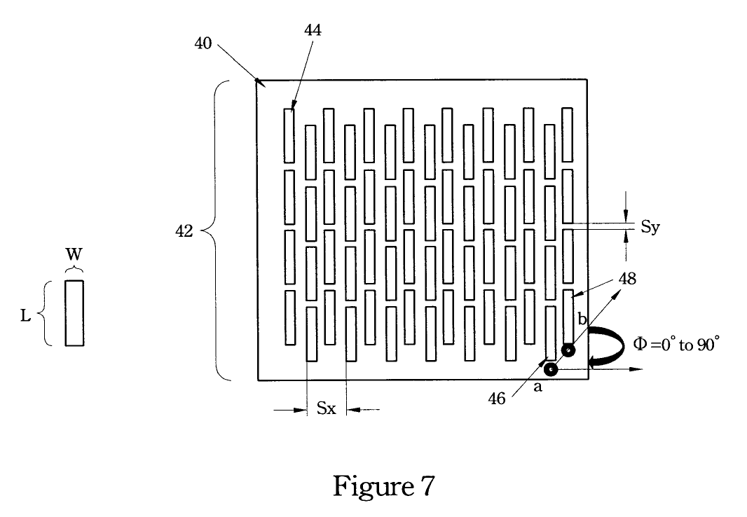

FIG. 7 is a diagram of a specially-designed OCD pattern for optimizing lithography energy/focus. As shown in FIG. 7, photomask 10 includes an optical critical dimension (OCD) pattern 42. OCD pattern 42 is a non-periodic type pattern, which is more flexible compared to OCD pattern 12 in FIG. 1. OCD pattern 42 comprises a plurality of segments 44. Each segment 44 has a width w that is less than a length L. The plurality of segments 44 may have the same dimension and geometry. The plurality of segments 44 are separated from one another by a vertical spacing Sy and a horizontal spacing Sx. However, the plurality of segments 44 may be arranged as a line pattern. In a line pattern, the vertical spacing Sy between the plurality of segments 44 is zero. In this example, segment 48 is located at angle φ, which is between 0 to 90 degrees, from segment 46. With OCD pattern 42, the focus direction may be determined based on measurements of LES or SWA.

In summary, a method and a system for optimizing lithography focus/energy are provided using a specially-designed OCD pattern, such as OCD pattern shown in FIG. 1 or 7. Better data quality and resolution are provided in the OCD library, such as OCD library shown in FIG. 6, based on the analysis data. In addition, early error warnings may be provided based on the analysis data. Furthermore, focus direction may now be determined from the lookup tables based on inline measurements of LES or SWA using the specially-designed OCD pattern.

It is to be understood that the following disclosure provides different embodiments, or examples, for implementing different features of various embodiments. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not itself dictate a relationship between various embodiments and/or configurations discussed.

1. A method for optimizing lithograph focus and energy, the method comprising:
receiving a wafer having a plurality of patterns;
measuring critical dimension, line-end shortening, and side-wall angle of the plurality of patterns using an integrated metrology equipment;
performing a spectrum analysis in a simulated spectra library to form analysis data;
storing the analysis data into a plurality of lookup tables of an optical critical dimension library; and
performing a lookup of the plurality of lookup tables to determine a focus or energy of the wafer.

2. The method of claim 1, wherein each of the plurality of patterns includes an optical critical dimension pattern comprising a plurality of segments.

3. The method of claim 1, wherein performing a spectrum analysis comprises:
comparing critical dimension measurements, line-end shortening measurements, and side-wall angle measurements against simulation results in the simulated spectra library.

4. The method of claim 1, wherein the simulated spectra library stores results of simulation of the wafer based on inputs comprising a pitch, optical properties of materials, a materials stack, and a range.

5. The method of claim 4, wherein the simulation of the wafer identifies whether a measured spectrum of the wafer is sensitive to change of focus direction.

6. The method of claim 1, wherein performing a lookup of the plurality of lookup tables to determine a focus or energy of the wafer comprises:
performing a lookup of a lookup table in the plurality of lookup tables comprising critical dimension measurements.

7. The method of claim 1, wherein performing a lookup of the plurality of lookup tables to determine a focus or energy of the wafer comprises:
performing a lookup of a lookup table in the plurality of lookup tables comprising line-end shortening measurements.

8. The method of claim 1, wherein performing a lookup of the plurality of lookup tables to determine a focus or energy of the wafer comprises:
performing a lookup of a lookup table in the plurality of lookup tables comprising side-wide angle measurements.

9. The method of claim 1, wherein performing a lookup of the plurality of lookup tables to determine a focus or energy of the wafer comprises:
performing a lookup of a lookup table in the plurality of lookup tables comprising a combination of critical dimension measurements, line-end shortening measurements, and side-wide angle measurements.

10. The method of claim 2, wherein the optical critical dimension pattern is a non periodic type pattern.

11. The method of claim 2, wherein the optical critical dimension pattern is a line pattern comprising a zero vertical spacing between the plurality of segments.

12. The method of claim 2, wherein a width of each of the plurality of segments is less than a length of each of the plurality of segments.

13. The method of claim 2, wherein the plurality of segments have a common dimension and geometry.

14. The method of claim 2, wherein the plurality of segments are separated from one another by a predefined and consistent vertical spacing and horizontal spacing.

15. The method of claim 2, wherein one segment in the plurality of segments is located at an angle between about 0 to about 90 degrees from another segment in the plurality of segments.

16. The method of claim 1, wherein performing a lookup of the plurality of lookup tables to determine a focus or energy of the wafer comprises performing a lookup of the plurality of lookup tables to determine a focus direction.

17. The method of claim 1, wherein the integrated metrology equipment is integrated into a process tool to measure critical dimension, line-end shortening, and side-wall angle of the plurality of photomasks from within the process tool.

18. The method of claim 1 wherein measuring critical dimension, line-end shortening, and side-wall angle of the plurality of patterns are performed substantially simultaneously using the integrated metrology equipment.

19. The method of claim 1, wherein performing a lookup of the plurality of lookup tables to determine a focus or energy of the wafer comprises:
identifying a first focus or energy and a second focus or energy based on the line-end shortening of the plurality of photomasks; and
identifying the focus or energy of the wafer from one of the first and second focus or energy based on the side-wide angle of the plurality of photomasks.

20. A photomask for optimizing lithography focus and energy, the photomask comprising a non-active region having a plurality of segments, each segment having a width and a length and each segment being spaced vertical.

21. The photomask of claim 20, wherein the plurality of segments are separated from one another by a vertical spacing Sy and a horizontal spacing Sx.

22. The photomask of claim 20, wherein a width of each of the plurality of segments is less than a length of each of the first and second plurality of segments.

23. The photomask of claim 20, wherein one segment is located at an angle of about less than 90 degrees from another segment in the plurality of segments.

24. An integrated circuit for optimizing lithography focus or energy comprising:
a region having an array comprising a plurality of segments, wherein each of the plurality of segments has a length and a width;
a vertical spacing Sy between the plurality of segments arranged in a vertical direction;
a horizontal spacing Sx between the plurality of segments arranged in a horizontal direction;
wherein one segment is located at an angle of about less than 90 degrees from another segment in the plurality of segments.

25. A system for optimizing lithography focus or energy of an integrated circuit comprising:
a simulation engine for simulating a wafer based on at least one predetermined input;
an integrated metrology equipment for measuring a plurality of predetermined parameters of the wafer; and
performing an analysis between results of the simulation engine and the integrated metrology equipment to determine an optimized parameter of the wafer.
